(19) United States
(12) Patent Application Publication
(10) Pub. No.: US 2023/0261116 A1
(43) Pub. Date: Aug. 17, 2023

(54) SEMICONDUCTOR DEVICE WITH LOW PINCH-OFF VOLTAGE AND METHODS FOR MANUFACTURING THE SAME

(71) Applicant: Chengdu Monolithic Power Systems Co., Ltd., Chengdu (CN)

(72) Inventors: Daping Fu, Chengdu (CN); Yanjie Lian, Chengdu (CN)

(21) Appl. No.: 18/170,034

(22) Filed: Feb. 16, 2023

(30) Foreign Application Priority Data
Feb. 17, 2022 (CN) 202210149364.0

(51) Int. Cl. H01L 29/808; H01L 27/085; H01L 21/8232

(52) U.S. Cl. CPC H01L 29/808; H01L 27/085; H01L 21/8232

(57) ABSTRACT

A semiconductor device includes a junction field effect transistor (JFET) device. The JFET device includes a substrate, a first well region, a first source region, a first drain region, a first gate region and a second gate region. A channel region is formed between the first source region and the first drain region along a first direction. The first gate region and the second gate region are located within the channel region, the first gate region includes a first surface extending from a top surface to a bottom surface of the first gate region, and the second gate region includes a second surface extending from a top surface to a bottom surface of the second gate region. The first surface is facing a second direction perpendicular to the first direction toward the second surface. A method of manufacturing such semiconductor device is also provided.

### CROSS REFERENCE

This application claims the benefit of CN application No. 202210149364.0 filed on Feb. 17, 2022 and incorporated herein by reference.

### TECHNICAL FIELD

The present invention generally relates to a semiconductor device, and more particularly but not exclusively, to a junction field effect transistor (JFET) device having a low pinch-off voltage and a method for manufacturing the same.

### BACKGROUND OF THE INVENTION

JFET have been widely used in many applications such as start-up circuits and constant current sources since it can withstand high voltage and it has a predetermined pinch-off voltage. As there is demand to increase the efficiency, the pinch-off voltage of JFET is expected to be lower. For example, for constant current source circuits having a low power consumption, the pinch-off voltage of a JFET is expected to be 1.2 volts. Generally, the pinch-off voltage may be reduced by changing doping concentrations of the gate region and the well region of the JFET. However, this requires additional photomasks and process, and thus the manufacturing cost is increased.

Therefore, it is desirable to provide a JFET device having a low pinch-off voltage without increasing the manufacturing cost.

### SUMMARY OF THE INVENTION

Embodiments of the present invention are directed a semiconductor device. The semiconductor device includes a substrate, a first well region, a first source region, a first drain region, a first gate region, and a second gate region. The first well region is formed in a top surface of the substrate. The first source region and the first drain region are formed in the first well region. A channel region is formed between the first source region and the first drain region along a first direction. The first gate region and the second gate region are formed in the first well region. The first gate region and the second gate region are located within the channel region, the first gate region includes a first surface extending from a top surface to a bottom surface of the first gate region, and the second gate region includes a second surface extending from a top surface to a bottom surface of the second gate region. The first surface is facing a second direction perpendicular to the first direction toward the second surface.

Embodiments of the present invention are directed a semiconductor device. The semiconductor device includes a substrate, a first well region, a first source region, a first drain region, and a plurality of first gate regions. The first well region is formed in a top surface of the substrate. The first source region and the first drain region are formed in the first well region along a first direction. The first gate regions formed in the first well region between the first source region and the first drain region. The first gate regions are located along a second direction perpendicular to the first direction, each first gate region extends from a top surface to a bottom surface of the first well region. Multiple channel regions are formed between the first gate regions.

Embodiments of the present invention are also directed to a method for manufacturing a semiconductor device. The method includes multiple steps: in step S10, a substrate is provided; in step S20, a first well region is formed in a top surface of the substrate; in step S30, a first gate region, a second gate region are formed in the first well region, where the first gate region includes a first surface extending from the top surface to a bottom surface of the first gate region, the second gate region includes a second surface extending from the top surface to a bottom surface of the second gate, and the first surface is facing a first direction toward the second surface; in step 40, a first source region and a first drain region are formed in the first well region, where the first source region and the first drain region are located along a second direction perpendicular to the first direction.

Embodiments of the present invention may provide the JFET device having the low pinch-off voltage without requiring additional photomask.

### BRIEF DESCRIPTION OF DRAWINGS

For a better understanding of the invention, embodiments of the invention will be described in accordance with the following drawings, which are used for illustrative purpose only. The drawings illustrate only some of the features in an embodiment. It should be understood that the drawings are not necessarily to scale.

FIG. 1A is a schematic diagram of the structure of a JFET device 100, FIG. 1B is a schematic cross-sectional view of the JFET device 100 along line A-A′ of FIG. 1A.

FIG. 2A is a schematic diagram of the structure of a JFET device 200 according to an embodiment of the present invention, FIG. 2B is a schematic cross-sectional view of the JFET device 200 along line A-A′ of FIG. 2A.

FIG. 3 is a schematic top view of the JFET device 200 of FIG. 2A.

FIG. 4 is a schematic cross-sectional view of the JFET device 200 along line B-B′ of FIG. 3.

FIG. 5 is a schematic diagram of the structure of a JFET device 500 according to another embodiment of the present invention.

FIG. 6 is a schematic cross-sectional view of the JFET device 500 along line A-A′ of FIG. 5.

FIG. 7A is a schematic diagram of the structure of a JFET 700 according to another embodiment of the present invention, FIG. 7B is a schematic cross-sectional view of the JFET device 700 along line A-A′ of FIG. 7A.

FIG. 8A is a schematic top view of the JFET device 700 of FIG. 7A, FIG. 8B and FIG. 8C are schematic top view of the JFET device according to other embodiments of the present invention.

FIG. 9 is a schematic diagram of the structure of a JFET device 900 according to an embodiment of the present invention.

FIG. 10 is a schematic cross-sectional view of a semiconductor device 1200 according to another embodiment of the present invention.

FIG. 11 is a flow chart of a method 1300 for manufacturing the semiconductor device 1200 according to an embodiment of the present invention.

Similar elements are provided with similar reference numerals in different appended drawings.

### DETAILED DESCRIPTION OF THE INVENTION

Detailed description of various embodiments is provided merely to give examples. However, the present invention is not limited thereto. Plenty of specific details are included to provide a comprehensive understanding of the present invention. However, one skilled in the relevant art will recognize that the present invention can be practiced without one or more specific details, or with other methods, components, materials, etc. In other instances, well-known structures, materials, processes or operations are not shown or described in detail to avoid obscuring aspects of the present disclosure.

Throughout the specification and claims, spatially relative terms such as “left”, “right”, “in”, “out”, “up”, “down”, “above”, “below”, “on top of”, “bottom”, “on”, “over”, “under” and the like, if any, are used herein for descriptive purposes and not necessarily for describing permanent relative positions. It should be understood by those skilled in the art that such terms are interchangeable under appropriate circumstances such that embodiments of the technology described herein are, for example, capable of operation in other orientations than those illustrated or otherwise described herein. For example, when an element, such as a layer, region, or substrate, is described as being “above”, or “on top of” another element, that is, the element is directly “on” the other element, or there is one or more elements (a middle element/layer) between the two elements. Additionally, when an element is “coupled to” or “connected to” the other element, it means that the element is directly connected to or coupled to the other element, or indirectly connected to or coupled to the other element via an electrical or non-electrical manner. The terms “a,” “an,” and “the” includes plural reference as well, unless the context clearly indicates otherwise. The phrase “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may.

The symbols “+” and “−” when used to describe dopants or doped regions/zones are merely used to descriptively indicate relative dopant concentration levels, but not intend to specify or limit the dopant concentration ranges, nor intend to add other limitations to the dopants and doped regions/zones. For instance, both “N+ type” and “N− type” can be referred to as “N type” in more general terms, and both “P+ type” and “P− type” can be referred to as “P type” in more general terms. Those skilled in the art should understand that the meanings of the terms identified above do not necessarily limit the terms, but merely provide illustrative examples for the terms. As can be appreciated, the conductivity and doping of materials or regions disclosed herein may be varied, with appropriate changes to the conductivity and doping of other materials or regions, depending on the application.

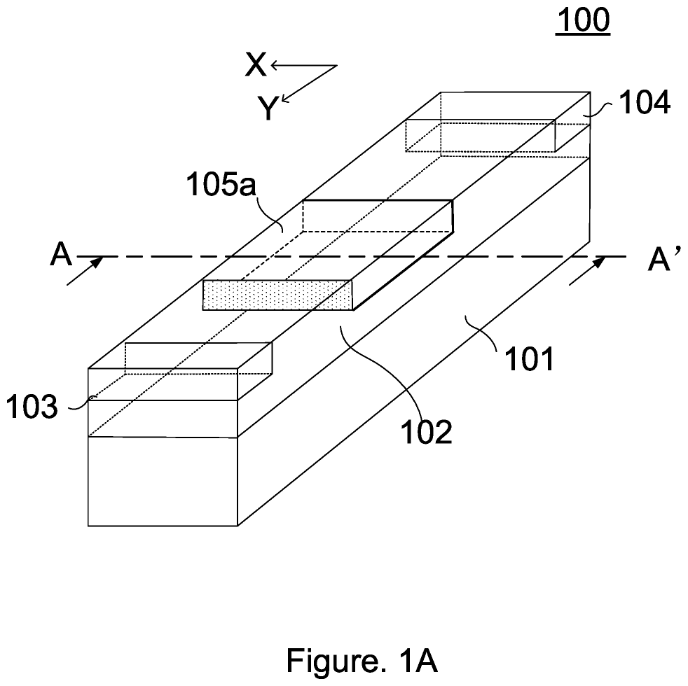

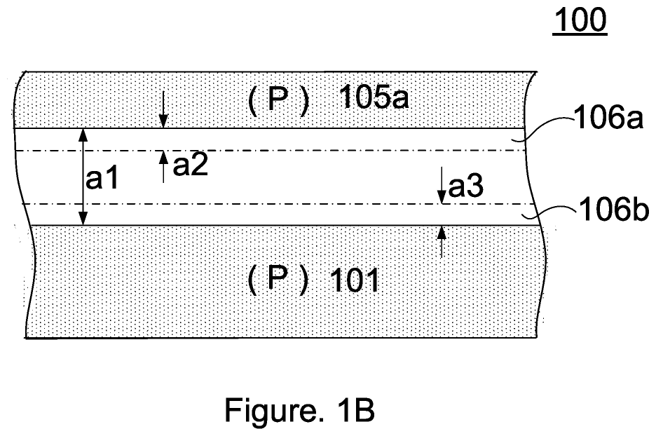

FIG. 1A is an example of a junction field effect transistor (JFET) device 100. The JFET device 100 includes a substrate 101, a well region 102, a source region 103, a drain region 104 and a top gate region 105a. The well region 102 is formed in the substrate 101. The source region 103 and the drain region 104 are formed in the well region 102 along a first direction (e.g., Y-axis). The top gate region 105a is formed between the source region 103 and the drain region 104 in the well region 102. The substrate 101 which is also used as a bottom gate region 101 and the top gate region 105 have a first conductivity type (e.g. P-type), while the well region 102, the source region 103 and the drain region 104 have a second conductivity type opposite to the first conductivity type (e.g. N-type).

FIG. 1B is a cross-sectional diagram at a dashed-dotted line A-A′ of FIG. 1A showing the JFET device 100. A channel region is formed between the top gate region 105a and the bottom gate 101. As shown in FIG. 1B, a depth of a channel region is a1-a2-a3, where a1 is a distance between the top gate region 105a and the bottom gate region 101, a2 is the thermal-equilibrium depletion width of a p-n junction formed between the top gate region 105a and the well region 102 and a3 is the thermal-equilibrium depletion width of a p-n junction formed between the bottom gate region 101 and the well region 102. When applying a negative voltage to the top gate region 105a and a positive voltage to the drain region 104, a top depletion regions 106a and a bottom depletion regions 106b spread throughout the channel, thus the channel resistance can be modulated. When the absolute voltage value applied to the top gate region 105a increases and reaches a threshold voltage, i.e., the pinch-off voltage V_{P}, the channel region may be pinched-off by the depletion regions 106a and 106b in the well region 102.

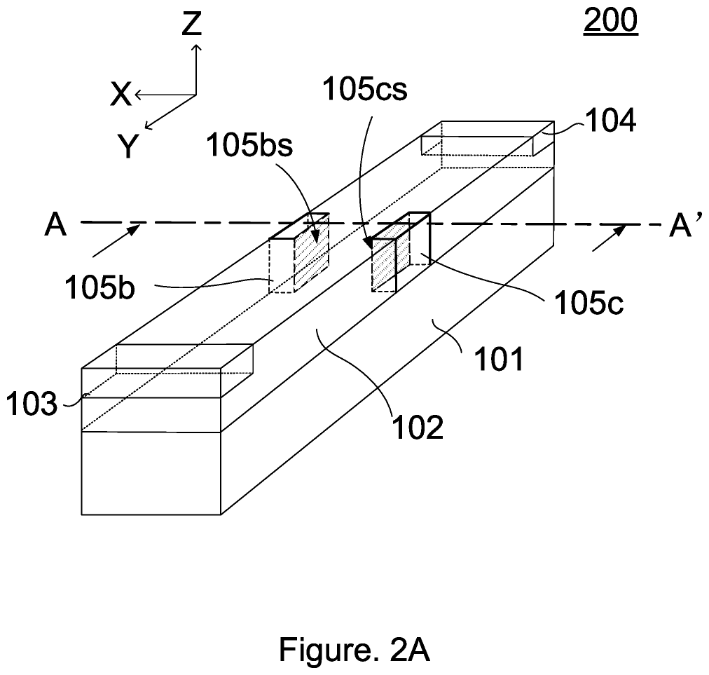

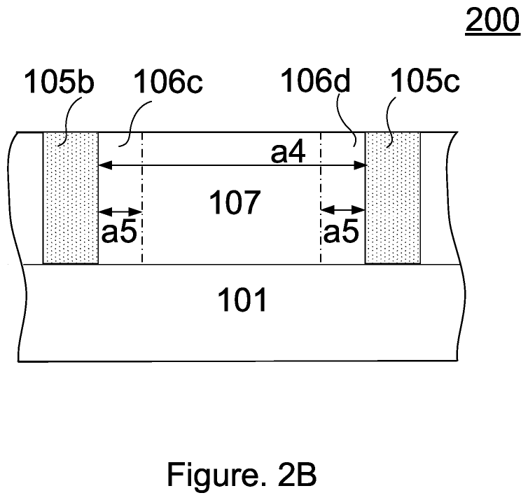

FIG. 2A schematically illustrates a structure diagram of a junction field effect transistor (JFET) device 200 in accordance with one embodiment of the present invention. The JFET device 200 includes a substrate 101, a well region 102, a source region 103, a drain region 104, a first gate region 105b and second gate region 105c. The well region 102 is formed in the top surface of the substrate 101. The source region 103, the drain region 104, the first gate region 105b and the second gate region 105c are all formed in the well region 102. A channel region is formed between the source region 103 and the drain region 104 along a first direction (e.g., Y-axis). The first gate region 105b and the second gate region 105c are located within the channel region. The first gate region 105b includes a first surface 105bs extending from the top surface to the bottom surface of the first gate region 105b and the second gate region 105c includes a second surface 105cs extending from the top surface to the bottom surface of the second gate region 105c, which are shown in slash in FIG. 2A. The first surface 105bs is facing a second direction (e.g., X-axis) perpendicular to the first direction toward to the second surface 105cs. Although the first gate region 105b and the second gate region 105c are shown in cuboid shape in FIG. 2A, they are not limited thereto.

FIG. 2B is a cross-sectional diagram at a dashed-dotted line A-A′ of FIG. 2A showing the JFET device 200. A channel region 107 is formed between the source region 103 and the drain region 104 along a first direction (e.g., Y-axis). As shown in FIG. 2B, the width of the channel region 107 is a4-a5, where a4 is a distance between the first surface 105bs of the first gate region 105b and the second surface 105cs of the second gate region 105c, a5 is the thermal-equilibrium depletion width of each p-n junction (assumed uniform for simplicity). When applying a negative voltage to the first gate region 105b and the second gate region 105c, and applying a positive voltage to the drain region 104, the depletion regions 106c and 106d spread throughout the channel, thus the channel resistance can be modulated. When the absolute voltage value applied to the first gate region 105b and the second gate region 105c increases and reaches a threshold voltage, i.e., the pinch-off voltage V_{P}, the channel region 107 may be pinched-off by the depletion regions 106c and 106d in the well region 102, that is, the induced drain-source current flowing in the channel region may decrease to an insignificant magnitude, nearly zero. In the embodiment of FIG. 2A, the pinch-off voltage V_{P} of the JFET device 200 may be adjusted by changing the spacing between the first gate region 105b and the second gate region 105c, in other words, the distance a4 between the first surface 105bs of the first gate region 105b and the second surface 105cs of the second gate region 105c. The smaller the spacing between the first gate region 105b and the second gate region 105c is, the smaller the value of the pinch-off voltage V_{P} is.

In the embodiment of FIG. 2A, the substrate 101, the first gate region 105b and the second gate region 105c have a first conductivity type (e.g. P-type), while the well region 102, the source region 103, and the drain region 104 have a second conductivity type opposite to the first conductivity type (e.g. N-type). It should be known that in other embodiments, the first conductivity type may be N-type and the second conductivity type may be P-type. In the embodiment of FIG. 2A, the first gate region 105b and the second gate region 105c penetrate through the well region 102, directly contact to the substrate 101 but not extend into the substrate 101, in other words, the depths of the first gate region 105b and the second gate region 105c are the same as the depth of the well region 102. In one embodiment, the first gate region 105a and the second gate region 105b may penetrate through the well region 102 and extend into the substrate 101. In another embodiment, the first gate region 105a and the second gate region 105b may not be contacted to the substrate 101, they may be coupled to each other via a metal layer, which is not shown here for simplicity. In another embodiment, the first gate region 105a, the second gate region 105b and the substrate 101 may be coupled to each other via a metal layer. In an embodiment, the doping concentration of the first gate region 105b and the second gate region 105c is approximately 1×10¹⁷ cm⁻³ to 9×10¹⁷ cm⁻³. In an embodiment, the doping concentration of the well region 102 is approximately 1×10¹⁶ cm⁻³ to 9×10¹⁶ cm⁻³. In an embodiment, the spacing between the first gate region 105b and the second gate region 105c is approximately 0.5 μm-2.5 μm. In one embodiment, the pinch-off voltage V_{P} of the JFET device 200 is approximately 1.1 volts-8 volts.

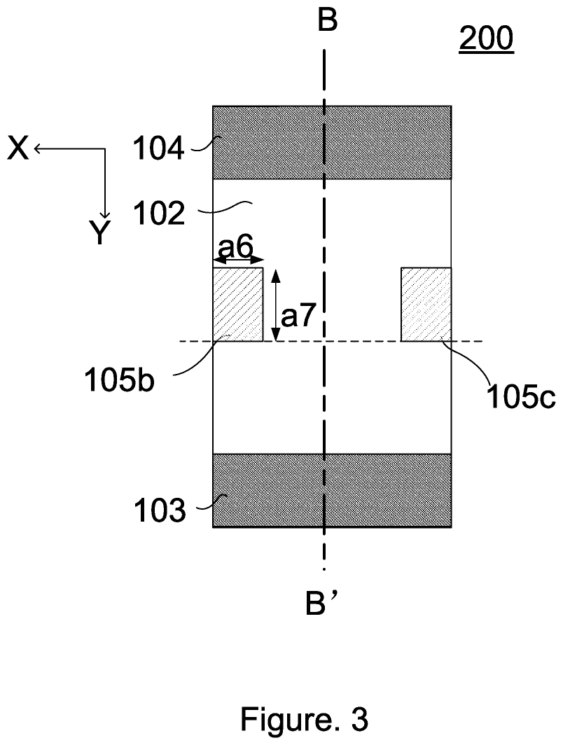

FIG. 3 shows a top view of the JFET device 200 of FIG. 2A. In the embodiment of FIG. 3, the top surfaces of the first gate region 105b and the second gate region 105c are in the same shape (e.g., square or rectangle). The width of the gate region along the first direction (e.g., X-axis) labeled with a6 is not larger than the length along a second direction (e.g., Y-axis) labeled with a7. Since the longer gate region in Y-axis extends the depletion region formed in the p-n junction between the gate region and the well region 102, the channel region of the JFET device 200 between the gate regions 105b and 105c may be pinched-off more easily. It should be known that in other embodiments, a6 is larger than a7. In the embodiment of FIG. 3, the first gate region 105b and the second gate region 105c align to a dotted line extending in the first direction (e.g., X-axis). In another embodiment, the first gate region 105b and the second gate region 105c do not align in this way.

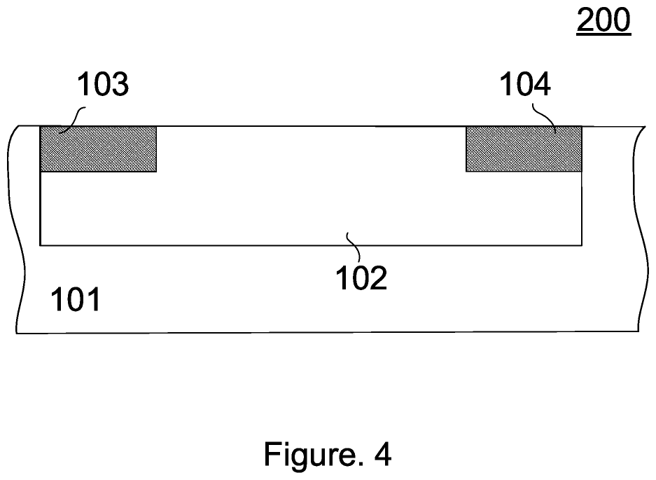

FIG. 4 shows a cross-sectional view of the JFET device 200 of FIG. 3 along line B-B′ of FIG. 3. In the embodiment of FIG. 4, the source region 103 has a higher doping concentration (e.g., N+) than the well region 102 (e.g., N). In an implementation, the doping concentration of the source region 103 and the drain region 104 ranges from 1×10²⁰ cm⁻³ to 1×10²² cm⁻³.

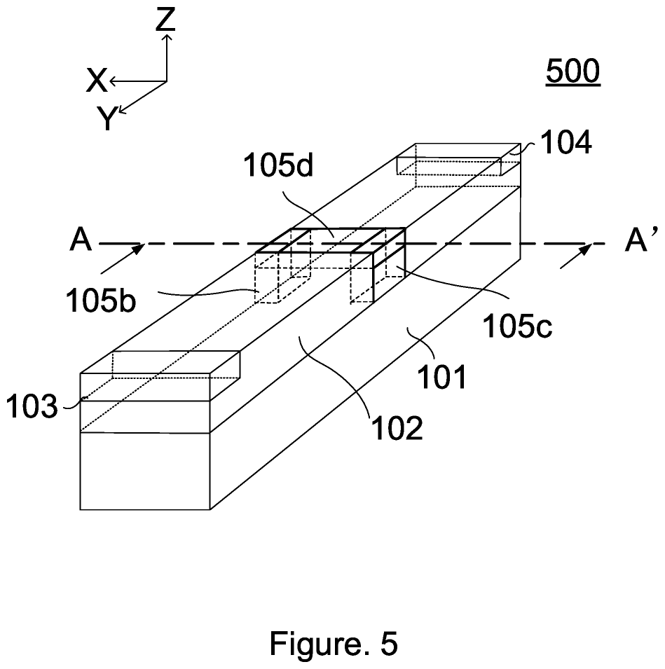

FIG. 5 schematically illustrates a structure diagram of a JFET device 500 in accordance with an embodiment of the present invention. The only difference between the JFET device 500 and the JFET device 200 is that the JFET 500 further includes a third gate region 105d formed on the surface of the well region 102 and connected to the first gate region 105b and the second gate region 105c. That is, the first gate region 105b, the second gate region 105c and the third gate region 105d constitute a u-shaped gate region. In one embodiment, the depth of the third gate 105d is smaller than that of the well region 102. As shown in FIG. 5, the conductivity type of the third gate region 105d and the conductivity type of the first gate region 105b and the second gate region 105c are the same (e.g., P-type). In other words, the third gate 105d is physically connected to the first gate region 105b and the second gate region 105c, and electrically coupled to the first gate region 105b and the second gate region 105c since they have the same conductivity type.

When applying a negative voltage to the first gate region 105b, the second gate region 105c and the third gate region 105d, and applying a positive voltage to the drain region 104, the p-n junction formed between the first gate region 105b and the well region 102, the p-n junction formed between the second gate region 105c and the well region 102 and the p-n junction formed between the third gate region 105d and the well region 102 are all reversed biased. The depletion regions of each p-n junction spread throughout the channel, thus the channel resistance can be modulated. In contrast to the JFET device 200 as shown in FIG. 2A, due to additional p-n junction formed between the third gate region 105d and the well region 102, the channel region of the JFET device 500 may be pinched-off more easily than that of the JFET device 200. Thus, the pinch-off voltage V_{P} of the JFET device 500 is lower than that of the JFET device 200.

In an embodiment, the third gate region 105d has a higher doping concentration than the first gate region 105b and the second gate region 105c. For instance, the doping concentration of the first gate region 105b and the second gate region 105c is approximately 1×10¹⁷ cm⁻³, and the doping concentration of the third gate region 105d ranges from 1×10²⁰ cm⁻³ to 1×10²² cm⁻³. In the embodiment of FIG. 5, the first gate region 105b, the second gate region 105b and the third gate region 105d have the same conductivity type, and are physically connected and electrically coupled to each other. It should be understood that in some embodiments, the JFET device 500 may further include a metal layer (not shown) configured to connect the first gate region 105b, the second gate region 105c, and the third gate region 105d together to achieve better electrical connection characteristics. In another embodiment, the first gate region 105b, the second gate region 105c, the third gate region 105d and the substrate 101 may be coupled together by a metal layer (not shown).

It should be noted that, the size (length, width, and height) and the location of the gate regions (including the first gate regions 105b, and the second gate region 105c and the third gate region 105d) could be adjusted according to practical applications in order to achieve the desirable pinch-off voltage of the JFET. For instance, the length/width of the third gate region 105d could be different from the length/width of the first gate region 105b. In some implementations, the first gate regions 105b, the second gate region 105c and the third gate region 105d constitute a H-shaped gate region. However, the present invention is not limited thereto.

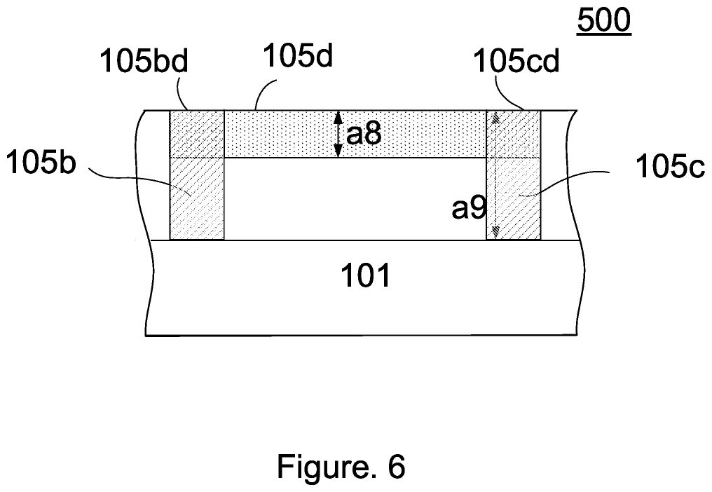

FIG. 6 shows a schematic cross-sectional view of the JFET device 500 of FIG. 5 along the line A-A′ of FIG. 5. As shown in FIG. 6, the depth of the third gate region 105d labeled with a8 is smaller than the depths of the first gate region 105b and the second gate region 105c labeled with a9. In the embodiment of FIG. 6, a8 is small than the depth of the well region 102. In one embodiment, a8 is less than half of the depth of the well region 102. As shown in FIG. 6, the third gate region 105d has a first area 105bd located on top of the first gate region 105b and a second area 105cd located on top of the second gate region 105c.

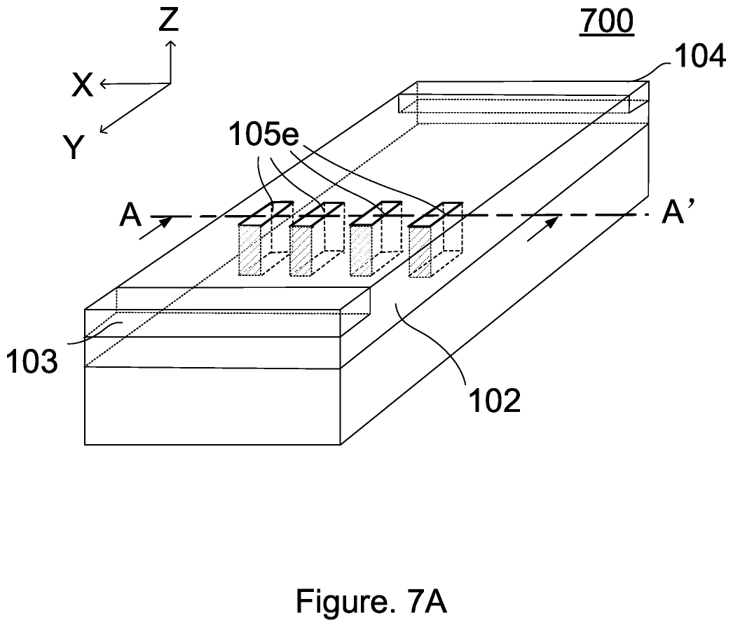

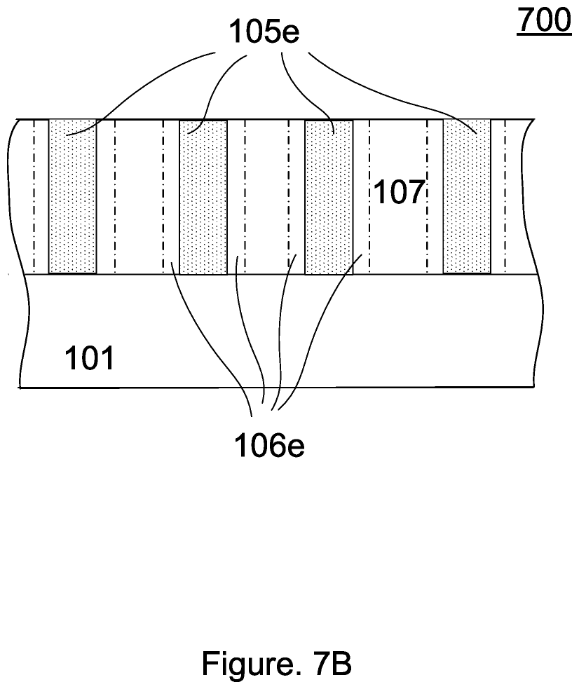

FIG. 7A schematically illustrates a structure diagram of a junction field effect transistor (JFET) device 700 in accordance with one embodiment of the present invention. The JFET device 700 includes a substrate 101, a well region 102, a source region 103, a drain region 104 and a plurality of first gate regions 105e. The well region 102 is formed in the top surface of the substrate 101. The source region 103, the drain region 104, and the plurality of first gate regions 105e are all formed in the well region 102. The source region 103 and the first drain region are located along a first direction (e.g., Y-axis). The first gate regions 105e are located along a second direction (e.g., X-axis). Each first gate region 105e extends from a top surface to a bottom surface of the first well region 102. Multiple channel regions are formed between the first gate regions. For instance, each first gate region includes two parallel surfaces which are perpendicular to the substrate surface (e.g., XY plane). Each surface is facing toward the surface of an adjacent first gate region 105e. Although the plurality of first gate regions 105e are shown in cuboid shape in FIG. 7A, they are not limited thereto.

FIG. 7B is a cross-sectional diagram at a dashed-dotted line A-A′ of FIG. 7A showing the JFET device 700 without applied bias on the plurality of first gate regions 105e or on the drain region 104 with respect to the source region 103. The channel region 107 is separated into several subareas by the plurality of first gate regions 105e. When applying a negative voltage to the plurality of first gate regions 105e, and applying a positive voltage to the drain region 104, the depletion regions 106e spread throughout the subareas of the channel region 107, thus the channel resistance can be modulated. When the absolute voltage value applied to plurality of first gate regions 105e increases and reaches a threshold voltage, i.e., the pinch-off voltage V_{P}, the channel region 107 may be pinched-off by the depletion regions 106e in the well region 102, that is, the induced drain-source current flowing in the channel region may decrease to an insignificant magnitude, nearly zero. In the embodiment of FIG. 7A, the pinch-off voltage V_{P} of the JFET device 700 may be adjusted by changing the spacing between two adjacent first gate regions 105e, in other words, the distance between two face-to-face first surfaces of two adjacent first gate regions 105e. The smaller the spacing between two adjacent first gate regions 105e is, the smaller the value of the pinch-off voltage V_{P} is.

In the embodiment of FIG. 7A, the substrate 101 and the plurality of first gate regions 105e have a first conductivity type (e.g. P-type), while the well region 102, the source region 103, and the drain region 104 have a second conductivity type opposite to the first conductivity type (e.g. N-type). It should be known that in other embodiments, the first conductivity type may be N-type and the second conductivity type may be P-type. In the embodiment of FIG. 7A, the plurality of first gate regions 105e penetrate through the well region 102, directly contact to the substrate 101 but not extend into the substrate 101, in other words, the depths of the plurality of first gate regions 105e are the same as the depth of the well region 102. In one embodiment, the plurality of first gate regions 105e may penetrate through the well region 102 and extend into the substrate 101. In another embodiment, the plurality of first gate regions 105e may not be contacted to the substrate 101, they may be coupled to each other via a metal layer, which is not shown here for simplicity. In another embodiment, the plurality of first gate regions 105e and the substrate 101 may be coupled to each other via a metal layer. In an embodiment, the doping concentration of the plurality of first gate regions 105e is approximately 1×10¹⁷ cm⁻³ to 9×10¹⁷ cm⁻³. In an embodiment, the doping concentration of the well region 102 is approximately 1×10¹⁶ cm⁻³ to 9×10¹⁶ cm⁻³. In an embodiment, the spacing between the any two adjacent first gate regions 105e is the same and approximately 0.5 μm-2.5 μm. In one embodiment, the pinch-off voltage V_{P} of the JFET device 700 is approximately 1.1 volts-8 volts.

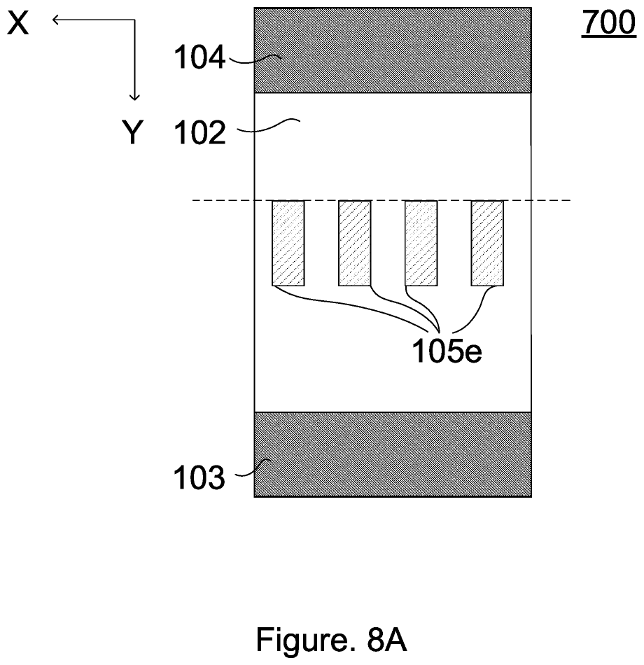

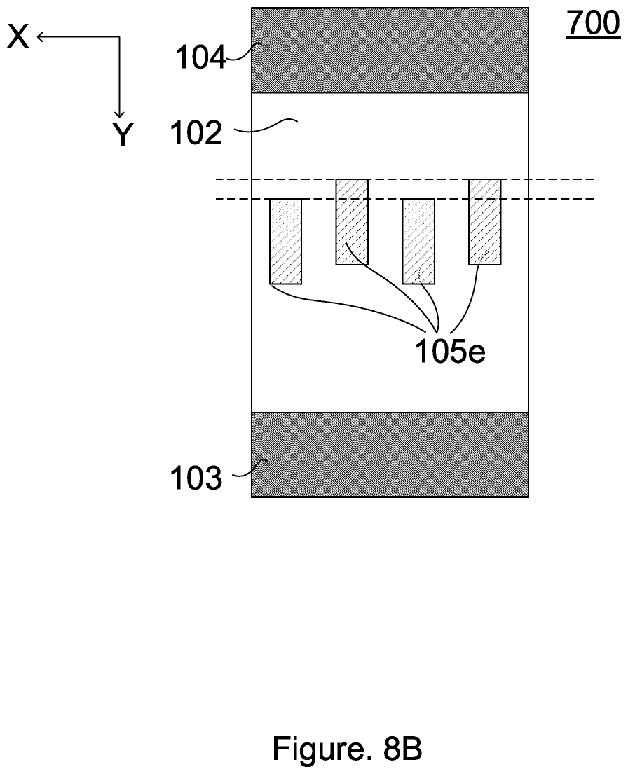

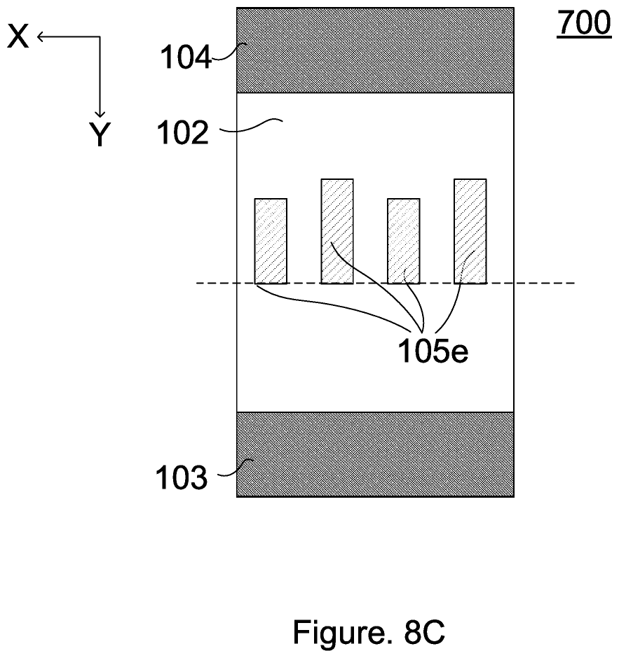

FIG. 8A shows a top view of the JFET device 700 of FIG. 7A. In the embodiment of FIG. 8A, the first gate regions 105e are in the same shape (e.g., rectangle). The width of the gate region 105e along the first direction (e.g., X-axis) is not larger than the length along a second direction (e.g., Y-axis). It should be known that in other embodiments, a side length along the first direction (e.g., X-axis) is larger than another side length along a second direction (e.g., Y-axis). In the embodiment of FIG. 8A, the first gate regions 105e align to each other with a dotted line extending in the first direction (e.g., X-axis). In other embodiments, the plurality of first gate regions 105e are partially aligned along the first direction (e.g., X-axis). In other words, the first gate regions 105e are not necessary to be perfectly aligned to each other as long as a part of the first gate regions 105e has a surface facing the X-axis direction toward a surface of the adjacent first gate regions 105e. For example, as shown in FIG. 8B, the first gate regions 105e are divided into two groups. Any two adjacent first gate regions 105e belong to different groups. The two groups are aligned with two different dotted lines along the X-axis. FIG. 8C shows another possible arrangement of the first gate regions 105e. In the embodiment of FIG. 8C, the plurality of first gate regions 105e are divided into two groups and any two adjacent first gate regions 105e belong to different groups. The exposed surfaces of these two group of first gate regions 105e are in rectangle shape while one group first gate regions 105e include larger length along the second direction (e.g., Y-axis) than the other group first gate regions 105e. These two groups of the first gate regions 105e align to a same dotted line extending in the first direction (e.g., X-axis).

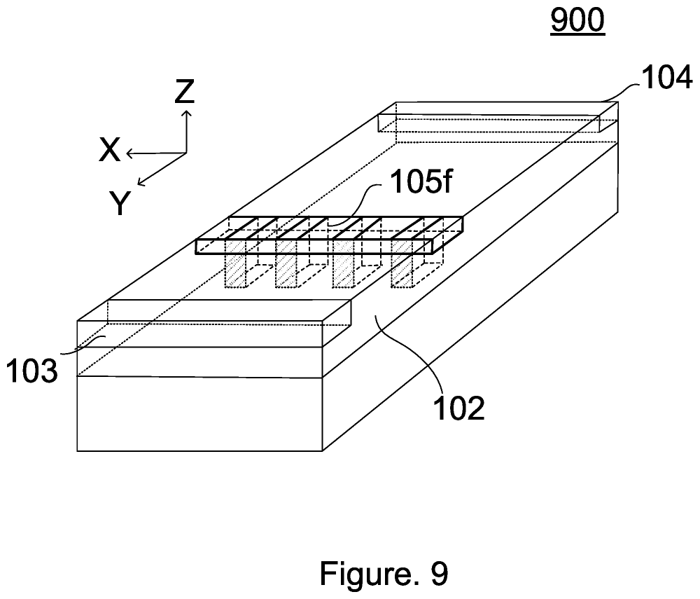

FIG. 9 schematically illustrates a structure diagram of a JFET device 900 in accordance with an embodiment of the present invention. The only difference between the JFET device 700 and the JFET device 900 is that the JFET 900 further includes a second gate region 105f formed on the surface of the well region 102 and connected to the plurality of first gate regions 105e. That is, the second gate region 105f and the plurality of first gate regions 105e constitute a π-shaped gate region. In one embodiment, the depth of the second gate 105f is smaller than that of the well region 102. As shown in FIG. 9, the conductivity type of the second gate region 105f and the conductivity type of the first gate regions 105e are the same (e.g., P-type). In other words, the second gate 105f is physically connected to the plurality of first gate regions 105e, and electrically coupled to plurality of first gate regions 105e since they have the same conductivity type. The working principle of JFET device 900 is similar to the working principle of JFET device 500 of FIG. 5 as described above, and thus are omitted. It should be noted that, the size (length, width, and height) and the location of the gate regions (including the first gate regions 105e and the second gate region 105f) could be adjusted according to practical applications in order to achieve the desirable pinch-off voltage of the JFET. For instance, the length/width of the second gate region 105f could be different from the length/width of the first gate region 105e. In some implementations, the first gate regions 105e and the second gate region 105f constitute a H-shaped gate region. However, the present invention is not limited thereto.

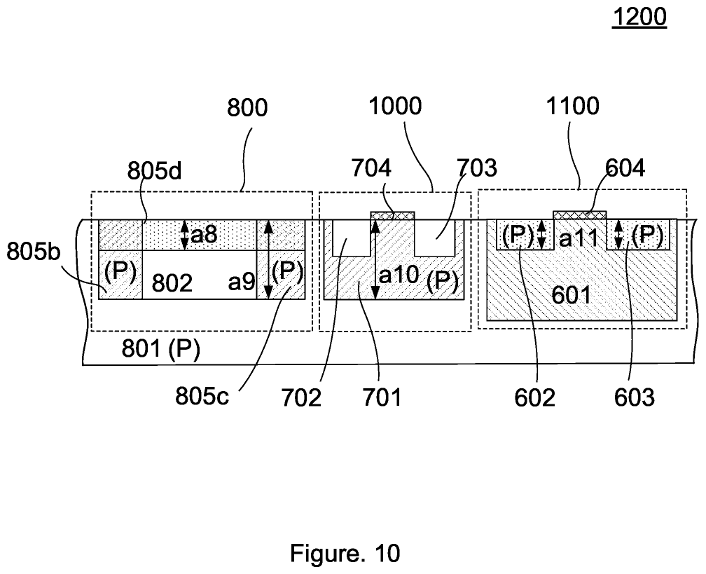

FIG. 10 shows a schematic cross-sectional view of a semiconductor structure 1200 in accordance with an embodiment of the present invention. The semiconductor structure 1200 includes a JFET device 800, an N-type MOS (NMOS) device 1000 and a P-type MOSFET (PMOS) device 1100. In the embodiment of FIG. 10, the JFET device 800 has the same structure as the JFET device 500, thus has the same cross-sectional view as the JFET device 500 shown in FIG. 6. It should be understood that in other embodiments, the JFET device 800 may be realized by other JFET structures, for example, the JFET device 200 as shown in FIG. 2A, the JFET device 700 shown in FIG. 7A, or the JFET device 900 shown in FIG. 9.

In FIG. 10, the JFET device 800 is formed on the substrate 801. The JFET device 800 includes a well region 802 formed in the semiconductor substrate 801. The JFET 800 includes a first gate region 805b, a second gate region 805c and a third gate region 805d. In an embodiment, the depth of the third gate region 805d (labeled with a8) is smaller than the depth of the first gate region 805b and the second gate region 805c (labeled with a9). In one implementation, a8 is less than half of the depth of the well region 802. The JFET device 800 further includes a source region and a drain region formed in the well region 802. The source region and the drain region are not shown in FIG. 10 since FIG. 10 is the cross-sectional view of the JFET device 800 along the first direction (e.g., X-axis).

Referring back to FIG. 10, the NMOS device 1000 is formed in a second well region 701. The NMOS device 1000 includes a source region 702, a drain region 703 and a gate region 704. In FIG. 10, the source region 702 and the drain region 703 have the second conductivity type (e.g. N-type in FIG. 10), while the second well region 701 have the first conductivity type (e.g. P-type in FIG. 10). The gate region 704 is generally formed via depositing and etching silicon oxides and polysilicon. In the embodiment as shown in FIG. 10, the depths of the first gate region 805b and the second gate region 805c (labeled with a9) is the same as the depth of the second well region 701 (labeled with a10). Therefore, the second well region 701, the first gate region 805b and the second gate region 805c could be formed simultaneously. In other words, the second well region 701, the first gate region 805b and the second gate region 805c are formed using the same photomask (i.e., the photomask used to form a P well region).

In a CMOS fabrication process, the photomask used to form the P/N well region is essential for fabricating basic semiconductor devices, such as NMOS and PMOS devices. For instance, the NMOS device and the PMOS device are respectively accommodated in the P well region and the N well region, and thus the photomask used to form the P well region and the photomask used to form the N well region are necessary in the CMOS fabrication process. In the embodiment of FIG. 10, by using the existed photomask used to form the P well region (the second well region 701), the first gate region 805b and the second gate region 805c could be formed simultaneously without adding additional photomask and process. Thus, the manufacturing cost could be saved.

Referring back to FIG. 10, in some embodiments, the semiconductor structure 1200 further includes the PMOS device 1100. The PMOS device 1100 is formed in a third well region 601. The PMOS device 1100 includes a source region 602, a drain region 603 and a gate region 604. In FIG. 10, the third well region 601 have the second conductivity type (e.g. N-type), while the source region 602 and the drain region 603 may have the first conductivity type (e.g. P-type). The gate region 604 is generally formed via depositing and etching silicon oxides and polysilicon. It should be noted that although the third well region 601 has the same conductivity type as the first well region 802, in one embodiment, the third well region 601 and the first well region 802 are formed by using different photomasks. In one implementation, the doping concentration of the third well region 601 is different from the doping concentration of the first well region 802. In one implementation, the depth of the third well region 601 is different from the depth of the first well region 802.

In the embodiment of FIG. 10, the third gate region 805d, the source region 602 and the drain region 603 have the same conductivity type (e.g., P-type), the depths of the source region 602 and the drain region 603 (labeled with a11) is the same as the depth of third gate region 805d (labeled with a8). In one embodiment, the third gate region 805d of the JFET device 800, the source region 602 and the drain region 603 of the PMOS device 1100 may be simultaneously formed using the same photomask (i.e., the photomask used to form the source region 602 and the drain region 603). In another embodiment, the photomask used to form the third gate region 805d of the JFET device 800 is different from the photomask used to form the source region 602 and the drain region 603 of the PMOS device 1100. By using independent photomask to form the third gate region 805d, the electrical characteristics of the JFET device 800, such as the pinch-off voltage V_{P}, may be more precisely determined.

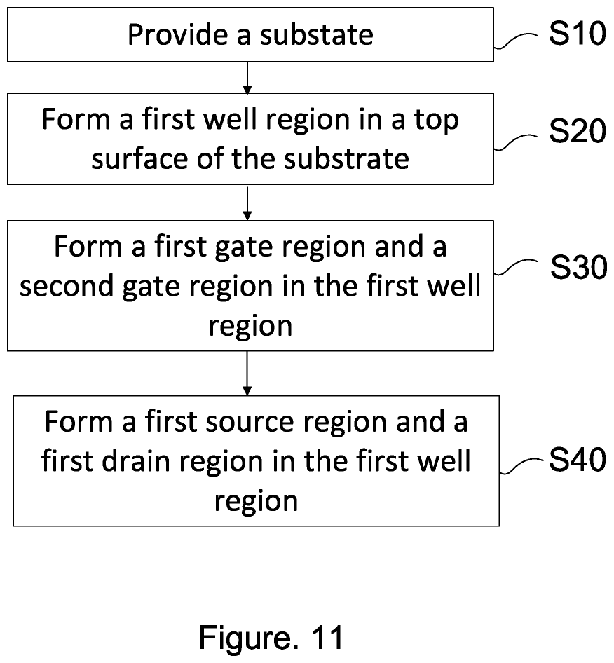

FIG. 11 schematically shows a flowchart of a method 1300 for manufacturing a semiconductor device in accordance with an embodiment of the present invention. The method 1300 includes multiple steps S10-S40. In step S10, a substrate is provided. In step S20, a first well region is formed in a top surface of the substrate. In step S30, a first gate region, a second gate region are formed in the first well region, where the first gate region includes a first surface extending from a top surface to a bottom surface of the first gate region, and the second gate region includes a second surface extending from a top surface to a bottom surface of the second gate region, and the first surface is facing a first direction toward the second surface. In step 40, a first source region and a first drain region are formed in the first well region along a second direction perpendicular to the first direction.

In one embodiment, the step S30 is performed by simultaneously forming the first gate region, the second gate region and a second well region using the same photomask.

In one embodiment, the step S40 is performed by implanting ions of a first doping type to form the first source region and the first drain region of the JFET device.

In one embodiment, the method 1300 further includes forming a third gate region on a surface of the first well region, connected to the first gate region and the second gate region.

In one embodiment, the method 1300 further includes the following steps. A second well region is formed in the substrate. A second source region and a second drain region are formed in the second well region. A fourth gate region is formed on top of the second well region. The second well region, the second source region, the second drain region, and the fourth gate region form a metal-oxide-semiconductor field-effect transistor (MOSFET). The first gate region, the second gate region and the second well region are formed through a first photomask.

In one embodiment, the method 1300 further includes the following steps. A third well region is formed in the substrate. A third source region and a third drain region are formed in the third well region. A fifth gate region is formed on top of the third well region. The third gate region, the third source region, and the third drain region, and the fifth gate region form a MOSFET. The third gate region, the third source region, and the third drain region are formed through a second photomask.

Although the flowchart of FIG. 13 shows a sequential steps. It is obvious to persons skilled the art that these steps could be performed in any order.

The present invention provides a JFET device with a lower pinch-off voltage. Specifically, the pinch-off voltage of the JFET device could be determined by adjusting the spacing between the gate regions. Additionally, the gate regions could be formed using the photomask to form the well region in the CMOS fabrication process, without additional photomask and process. Consequently, the pinch-off voltage of the JFET device can be reduced without increasing manufacturing cost.

While some embodiments of the present invention have been described in detail above, it should be understood, of course, these embodiments are for exemplary illustration only and are not intended to limit the scope of the present invention. Various modifications are contemplated and they obviously will be resorted to by those skilled in the art without departing from the spirit and the scope of the invention.

What is claimed is:

1. A semiconductor device comprising:
a substrate;
a first well region formed in a top surface of the substrate;
a first source region and a first drain region formed in the first well region;
a channel region formed between the first source region and the first drain region along a first direction; and
a first gate region and a second gate region formed in the first well region, wherein the first gate region and the second gate region are located within the channel region, the first gate region includes a first surface extending from a top surface to a bottom surface of the first gate region, and the second gate region includes a second surface extending from a top surface to a bottom surface of the second gate region;
wherein the first surface is facing a second direction perpendicular to the first direction toward the second surface.

2. The semiconductor device of claim 1, wherein the substrate, the first gate region, and the second gate region have a first conductivity type; wherein the first well region, the first source region and the first drain region have a second conductivity type; and the substrate, the first well region, the first gate region, the second gate region, the first source region and the first drain region form a junction field effect transistor (JFET).

3. The semiconductor device of claim 1, wherein a spacing between the first gate region and a second gate region ranges from 0.5 μm to 2.5 μm.

4. The semiconductor structure of claim 2, wherein a pinch-off voltage of the JFET is determined by a spacing between the first gate region and the second gate region.

5. The semiconductor structure of claim 2, wherein the JFET further comprising:
a third gate region, having the first conductivity type, formed on the top surface of the first well region and connected to the first gate region and the second gate region.

6. The semiconductor structure of claim 2, wherein a pinch-off voltage of the JFET ranges from 1.1 volts to 8 volts.

7. The semiconductor structure of claim 1, wherein the first gate region, the second gate region and the first well region have the same depth.

8. The semiconductor structure of claim 1, further comprising:
a second well region formed in the substrate;
a second source region and a second drain region formed in the second well region; and
a fourth gate region formed on top of the second well region;
wherein the second well region, the second source region, the second drain region, and the fourth gate region form a metal-oxide-semiconductor field-effect transistor (MOSFET); and
wherein the first gate region, the second gate region and the second well region have the same depth and the same conductivity type.

9. The semiconductor structure of claim 7, wherein the first gate region, the second gate region and the second well region have the same doping concentration.

10. The semiconductor structure of claim 7, wherein the first gate region, the second gate region and the second well region are formed through a first photomask.

11. The semiconductor structure of claim 5, further comprising:
a third well region formed in the substrate;
a third source region and a third drain region formed in the third well region; and
a fifth gate region formed on top of the third well region;
wherein the third gate region, the third source region, and the third drain region, and the fifth gate region form a MOSFET; and
wherein the third gate region, the third source region and the third drain region have the same depth and the same conductivity type.

12. The semiconductor structure of claim 10, wherein the third gate region, the third source region and the third drain region have the same doping concentration.

13. The semiconductor structure of claim 10, wherein the third gate region, the third source region and the third drain region are formed through a second photomask.

14. A semiconductor device, comprising:
a substrate;
a first well region formed in a top surface of the substrate;
a first source region, a first drain region formed in the first well region along a first direction; and
a plurality of first gate regions formed in the first well region between the first source region and the first drain region, wherein the first gate regions are located along a second direction perpendicular to the first direction, each first gate region extends from a top surface to a bottom surface of the first well region;
wherein multiple channel regions are formed between the first gate regions.

15. The semiconductor device of claim 13, wherein a spacing between any two adjacent first gate regions are the same, the spacing ranges from 0.5 μm to 2.5 μm.

16. The semiconductor device of claim 13, wherein the semiconductor device further comprising a second gate region formed on the top surface of the first well region and connected to at least two of the first gate regions.

17. A method for manufacturing a semiconductor device, comprising:
providing a substrate;
forming a first well region in a top surface of the substrate;
forming a first gate region and a second gate region in the well region; wherein the first gate region includes a first surface extending from the top surface to a bottom surface of the first gate region, the second gate region includes a second surface extending from the top surface to a bottom surface of the second gate, and the first surface is facing a first direction toward the second surface; and
forming a source region and a drain region in the well region along a second direction perpendicular to the first direction.

18. The method of claim 17, further comprising:
forming a second well region in the substrate;
forming a second source region and a second drain region in the second well region; and
forming a fourth gate region on top of the second well region;
wherein the first gate region, the second gate region and the second well region are formed through a first photomask.

19. The method of claim 17, further comprising:
forming a third gate region on a surface of the first well region, wherein the third gate region is connected to the first gate region and the second gate region.

20. The method of claim 19, further comprising:
forming a third well region in the substrate;
forming a third source region and a third drain region in the third well region; and
forming a fifth gate region on top of the third well region;
wherein the third gate region, the third source region, and the third drain region are formed through a second photomask.
